(19) United States
(12) Patent Application Publication
(10) Pub. No.: US 2024/0260254 A1
(43) Pub. Date: Aug. 1, 2024

(54) SEMICONDUCTOR DEVICE WITH VERTICAL BODY CONTACT AND METHODS FOR MANUFACTURING THE SAME

(71) Applicant: Micron Technology, Inc., Boise, ID (US)

(72) Inventors: Kamal M. Karda, Boise, ID (US); Haitao Liu, Boise, ID (US); Si-Woo Lee, Boise, ID (US); Chandra Mouli, Boise, ID (US)

(21) Appl. No.: 18/403,103

(22) Filed: Jan. 3, 2024

Related U.S. Application Data
(60) Provisional application No. 63/442,339, filed on Jan. 31, 2023.
(60) Provisional application No. 63/471,417, filed on Jun. 6, 2023.

(51) Int. Cl. H10B 12/00; H01L 23/528; H01L 29/423

(52) U.S. Cl. CPC H10B 12/33; H01L 23/5283; H01L 29/42392; H10B 12/03; H10B 12/482; H10B 12/488

(57) ABSTRACT

Methods, apparatuses, and systems related to a memory device having transistor body contacts that extend vertically across stacked circuit layers and connect to body portions of data access transistors are described. A memory device may include storage cells and corresponding access circuits on each of the stacked layers. The vertically extending transistor body contacts may provide a route for leakage away from data storage circuits when the data access transistors are off.

### CROSS-REFERENCE TO RELATED APPLICATIONS

The present application claims priority to U.S. Provisional Patent Application No. 63/442,339, filed Jan. 31, 2023, and claims priority to U.S. Provisional Patent Application No. 63/471,417, filed Jun. 6, 2023; the disclosures of which are incorporated herein by reference in their entirety.

### TECHNICAL FIELD

The disclosed embodiments relate to devices, and, in particular, to semiconductor devices with vertical body contact and methods for manufacturing the same.

### BACKGROUND

A semiconductor device can include one or more circuits, such as a combination of connected transistors, capacitors, and other similar circuit components, fabricated or embedded in semiconductor material. Some examples of the semiconductor device can include a semiconductor die, a package, a system-on-chip, a circuit card, or the like including the semiconductor-based circuits. Such semiconductor device can be configured for a variety of functions, as for a processor or a memory device (e.g., a volatile memory device, a non-volatile memory device, or a combination device).

With technological growth and increasing applications, the market is continuously looking for faster, more efficient, and smaller devices. To meet the market demand, the semiconductor devices are being pushed to the limit with various improvements. Improving devices, generally, may include increasing circuit density, reducing the circuit footprint, increasing operating speeds or otherwise reducing operational latency, increasing reliability, reducing power consumption, or reducing manufacturing costs, among other metrics. For example, three-dimensional (3D) architectures are being researched for semiconductor device designs.

### BRIEF DESCRIPTION OF THE DRAWINGS

FIG. 1 is a block diagram of an apparatus in accordance with an embodiment of the present technology.

FIG. 2 is a perspective cut-out view of an example 3D semiconductor device having a vertical body contact in accordance with an embodiment of the present technology.

FIG. 3 is a perspective view of an example circuit unit within the 3D semiconductor device of FIG. 2 in accordance with an embodiment of the present technology.

FIG. 4 is a top view of a first example arrangement of adjacent circuit units in accordance with an embodiment of the present technology.

FIG. 5 is a top view of a second example arrangement of adjacent circuit units in accordance with an embodiment of the present technology.

FIG. 6-FIG. 18 are example stages in manufacturing an example 3D semiconductor device in accordance with an embodiment of the present technology.

FIG. 19A-FIG. 19C are illustrations of various details regarding the first example 3D semiconductor device in accordance with an embodiment of the present technology.

FIG. 20A and FIG. 20B are illustrations of an adjusted example stage for manufacturing the second example 3D semiconductor device in accordance with an embodiment of the present technology.

FIG. 21 is a schematic view of an example aspect of the 3D semiconductor device in accordance with an embodiment of the present technology.

FIG. 22 is a flow diagram illustrating an example method of manufacturing a semiconductor device with a vertical body contact in accordance with an embodiment of the present technology.

FIG. 23 is a schematic view of a system that includes a semiconductor device in accordance with an embodiment of the present technology.

### DETAILED DESCRIPTION

As described in greater detail below, the technology disclosed herein relates to a semiconductor device having a vertical body contact, such as for memory systems, systems with memory devices, etc., and related methods.

In some embodiments, the semiconductor device can have a 3D architecture that includes transistors arranged in overlapping or stacked layers. To improve the control of the current flow, the transistors in the 3D architecture may have a gate-all-around (GAA) thin-film transistor (TFT) structure. The GAA structure can have the gate surrounding three or more faces of a channel where electric current flows.

Using a memory device (e.g., random-access memory (RAM)) as an illustrative example, the transistor configured to control access, such as for reads, writes, or both, to each memory cell can have the GAA TFT structure. In some embodiments, each memory cell may be connected to a corresponding digit-line (DL) across a laterally extending semiconductor substrate. A structure for a word-line (WL) can be disposed between and surround the semiconductor substrate. The memory device can include a vertically extending body contact that contacts the semiconductor substrate at a location across the WL from the memory cell and closer to the DL. Accordingly, in the 3D architecture, the vertically extending body contact can connect to semiconductor substrates and corresponding memory access circuits that are on multiple layers and arranged or aligned along a column.

The vertically extending body contact can provide reduced floating body effects that degrade the retention of the memory cell. Further, the vertically extending body contact can boost the current that flows through the memory access circuits (e.g., “on” current or Iₒₙ) while improving I_{off} by allowing higher doping for digit junctions and by having the body contact removed from (e.g., adjacent to) a path for the Iₒₙ.

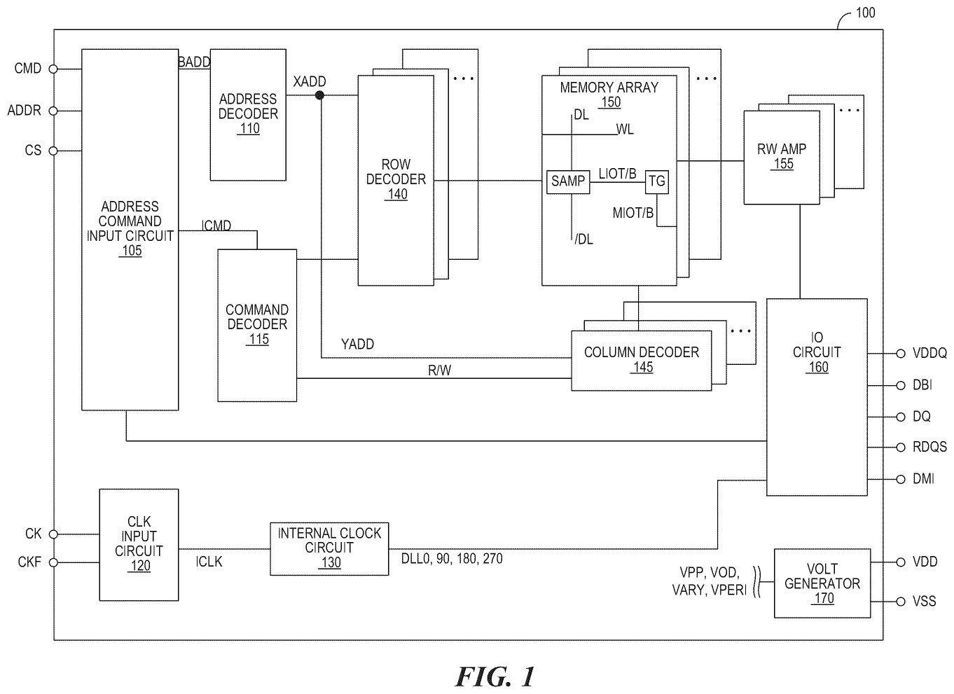

FIG. 1 is a block diagram of an apparatus 100 (e.g., a semiconductor die assembly, including a three-dimensional integration (3DI) device or a die-stacked package) in accordance with an embodiment of the present technology. For example, the apparatus 100 can include a DRAM or a portion thereof that includes one or more dies/chips.

The apparatus 100 may include an array of memory cells, such as memory array 150. The memory array 150 may include a plurality of banks (e.g., banks 0-15), and each bank may include a plurality of WLs, a plurality of DLs, and a plurality of memory cells arranged at intersections of the word-lines and the bit lines. Memory cells can include any one of a number of different memory media types, including capacitive, magnetoresistive, ferroelectric, phase change, or the like. Details regarding the structure of the WLs, the DLs, and the memory cells are described below.

The selection of a word-line WL may be performed by a row decoder 140, and the selection of a digit-line DL may be performed by a column decoder 145. Sense amplifiers (SAMP) may be provided for coupled digit-line DL and connected to at least one respective local I/O line pair (LIOT/B), which may in turn be coupled to at least respective one main I/O line pair (MIOT/B), via transfer gates (TG), which can function as switches. The sense amplifiers and transfer gates may be operated based on control signals from decoder circuitry, which may include the command decoder 115, the row decoders 140, the column decoders 145, any control circuitry of the memory array 150, or any combination thereof. The memory array 150 may also include plate lines and related circuitry for managing their operation.

The apparatus 100 may employ a plurality of external terminals that include command and address terminals coupled to a command bus and an address bus to receive command signals (CMD) and address signals (ADDR), respectively. The apparatus 100 may further include a chip select terminal to receive a chip select signal (CS), clock terminals to receive clock signals CK and CKF, data clock terminals to receive data clock signals WCK and WCKF, data terminals DQ, RDQS, DBI, DMI, power supply terminals VDD, VSS, and VDDQ.

The command terminals and address terminals may be supplied with an address signal and a bank address signal (not shown in FIG. 1) from outside. The address signal and the bank address signal supplied to the address terminals can be transferred, via a command/address (CA) input circuit 105, to an address decoder 110. The address decoder 110 can receive the address signals and supply a decoded row address signal (XADD) to the row decoder 140, and a decoded column address signal (YADD) to the column decoder 145. The address decoder 110 can also receive the bank address signal and supply the bank address signal to both the row decoder 140 and the column decoder 145.

The command and address terminals may be supplied with command signals (CMD), address signals (ADDR), and chip select signals (CS), from a memory controller and/or a nefarious chipset. The command signals may represent various memory commands from the memory controller (e.g., including access commands, which can include read commands and write commands). The chip select signal may be used to select the apparatus 100 to respond to commands and addresses provided to the command and address terminals. When an active chip select signal is provided to the apparatus 100, the commands and addresses can be decoded, and memory operations can be performed. The command signals may be provided as internal command signals ICMD to a command decoder 115 via the command/address input circuit 105. The command decoder 115 may include circuits to decode the internal command signals ICMD to generate various internal signals and commands for performing memory operations, for example, a row command signal to select a word-line and a column command signal to select a bit line. The command decoder 115 may further include one or more registers for tracking various counts or values (e.g., counts of refresh commands received by the apparatus 100 or self-refresh operations performed by the apparatus 100).

Read data can be read from memory cells in the memory array 150 designated by row address (e.g., address provided with an active command) and column address (e.g., address provided with the read). The read command may be received by the command decoder 115, which can provide internal commands to input/output circuit 160 so that read data can be output from the data terminals DQ, RDQS, DBI, and DMI via read/write amplifiers 155 and the input/output circuit 160 according to the RDQS clock signals. The read data may be provided at a time defined by read latency information RL that can be programmed in the apparatus 100, for example, in a mode register (not shown in FIG. 1). The read latency information RL can be defined in terms of clock cycles of the CK clock signal. For example, the read latency information RL can be a number of clock cycles of the CK signal after the read command is received by the apparatus 100 when the associated read data is provided.

Write data can be supplied to the data terminals DQ, DBI, and DMI according to the WCK and WCKF clock signals. The write command may be received by the command decoder 115, which can provide internal commands to the input/output circuit 160 so that the write data can be received by data receivers in the input/output circuit 160 and supplied via the input/output circuit 160 and the read/write amplifiers 155 to the memory array 150. The write data may be written in the memory cell designated by the row address and the column address. The write data may be provided to the data terminals at a time that is defined by write latency WL information. The write latency WL information can be programmed in the apparatus 100, for example, in the mode register. The write latency WL information can be defined in terms of clock cycles of the CK clock signal. For example, the write latency information WL can be a number of clock cycles of the CK signal after the write command is received by the apparatus 100 when the associated write data is received.

The power supply terminals may be supplied with power supply potentials VDD and VSS. These power supply potentials V_{DD} and V_{SS} can be supplied to an internal voltage generator circuit 170. The internal voltage generator circuit 170 can generate various internal potentials V_{PP}, V_{OD}, V_{ARY}, V_{PERI}, and the like based on the power supply potentials V_{DD} and V_{SS}. The internal potential V_{PP} can be used in the row decoder 140, the internal potentials V_{OD} and V_{ARY} can be used in the sense amplifiers included in the memory array 150, and the internal potential V_{PERI} can be used in many other circuit blocks.

The power supply terminal may also be supplied with power supply potential V_{DDQ}. The power supply potential V_{DDQ} can be supplied to the input/output circuit 160 together with the power supply potential V_{SS}. The power supply potential V_{DDQ} can be the same potential as the power supply potential V_{SS} in an embodiment of the present technology. The power supply potential V_{DDQ} can be a different potential from the power supply potential V_{DD} in another embodiment of the present technology. However, the dedicated power supply potential V_{DDQ} can be used for the input/output circuit 160 so that power supply noise generated by the input/output circuit 160 does not propagate to the other circuit blocks.

The clock terminals and data clock terminals may be supplied with external clock signals and complementary external clock signals. The external clock signals CK, CKF, WCK, WCKF can be supplied to a clock input circuit 120. The CK and CKF signals can be complementary, and the WCK and WCKF signals can also be complementary. Complementary clock signals can have opposite clock levels and transition between the opposite clock levels at the same time. For example, when a clock signal is at a low clock level a complementary clock signal is at a high level, and when the clock signal is at a high clock level the complementary clock signal is at a low clock level. Moreover, when the clock signal transitions from the low clock level to the high clock level the complementary clock signal transitions from the high clock level to the low clock level, and when the clock signal transitions from the high clock level to the low clock level the complementary clock signal transitions from the low clock level to the high clock level.

Input buffers included in the clock input circuit 120 can receive the external clock signals. For example, when enabled by a clock/enable signal from the command decoder 115, an input buffer can receive the clock/enable signals. The clock input circuit 120 can receive the external clock signals to generate internal clock signals ICLK. The internal clock signals ICLK can be supplied to an internal clock circuit 130. The internal clock circuit 130 can provide various phase and frequency controlled internal clock signals based on the received internal clock signals ICLK and a clock enable (not shown in FIG. 1) from the command/address input circuit 105. For example, the internal clock circuit 130 can include a clock path (not shown in FIG. 1) that receives the internal clock signal ICLK and provides various clock signals to the command decoder 115. The internal clock circuit 130 can further provide input/output (IO) clock signals. The IO clock signals can be supplied to the input/output circuit 160 and can be used as timing signals for determining output timing of read data and/or input timing of write data. The IO clock signals can be provided at multiple clock frequencies so that data can be output from and input to the apparatus 100 at different data rates. A higher clock frequency may be desirable when high memory speed is desired. A lower clock frequency may be desirable when lower power consumption is desired. The internal clock signals ICLK can also be supplied to the internal clock circuit 130 and thus various internal clock signals can be generated.

The apparatus 100 can be connected to any one of a number of electronic devices capable of utilizing memory for the temporary or persistent storage of information, or a component thereof. For example, a host device of apparatus 100 may be a computing device such as a desktop or portable computer, a server, a hand-held device (e.g., a mobile phone, a tablet, a digital reader, a digital media player), or some component thereof (e.g., a central processing unit, a co-processor, a dedicated memory controller, etc.). The host device may be a networking device (e.g., a switch, a router, etc.) or a recorder of digital images, audio and/or video, a vehicle, an appliance, a toy, or any one of a number of other products. In one embodiment, the host device may be connected directly to apparatus 100; although in other embodiments, the host device may be indirectly connected to memory device (e.g., over a networked connection or through intermediary devices).

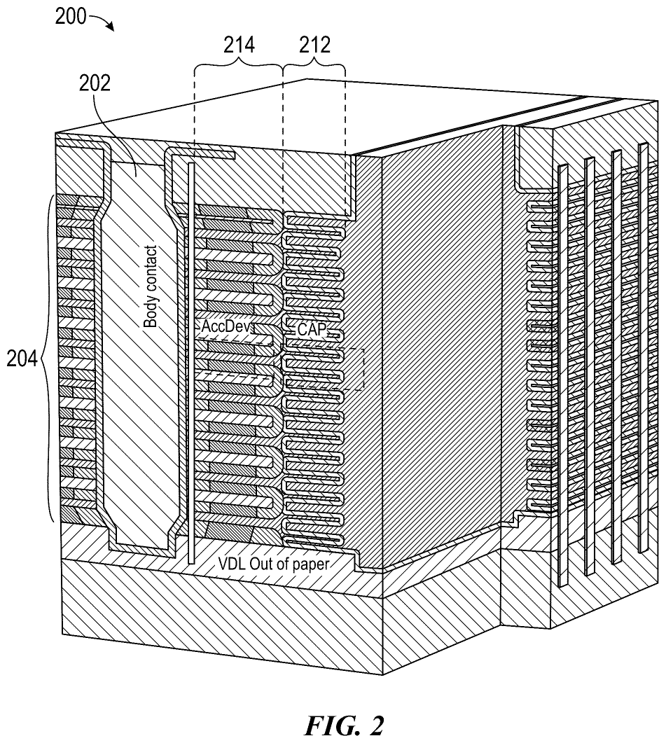

FIG. 2 is a perspective cut-out view of an example 3D semiconductor device 200 (e.g., the apparatus 100 of FIG. 1 or a portion thereof, such as the memory array 150 of FIG. 1) having a vertical body contact 202 in accordance with an embodiment of the present technology. The vertical body contact 202 can include an electrical connection for body portion of one or more transistors. For example, the device 200 can have circuits that include transistors arranged in stacked layers 204. One or more of the transistors or portions thereof in each layer can be located at a matching location, thereby having the transistors arranged along a column across the stacked layers. Such organization can be leveraged to have the vertical body contact 202 providing the electrical body connection to the transistors along the column.

Using the apparatus 100 as an example, each of the circuit layer 204 can include one or more data storage devices 212 (e.g., a capacitor or a similar circuit) that are each connected to a access circuit 214. Each of the storage devices 212 can include the memory cells that are configured to have multiple states, such as for charge storage, magnetic or resistive state, or the like, that represent stored data (e.g., ‘0’, ‘1’, or a combination thereof). The access devices 214 can include circuits, such as transistors, that are configured to set and/or read the states of the connected storage devices 212.

The storage devices 212 can be arranged (1) laterally across a layer, (2) vertically across layers (e.g., along one or more columns), or a combination thereof. Correspondingly, the access devices 214 can be arranged both laterally and vertically (e.g., along columns). For one or more such columns, the device 200 can include the vertical body contact 202 extending across the layers and connecting the vertically aligned access devices 214 to provide the transistor body connection. For example, the vertical body contact 202 can contact a semiconductor substrate or body at a location opposite or away from connected memory cells across the WL. In other words, the vertical body contact 202 and the DL can be on one side of the WL and the memory cell can be on the opposing side of the WL.

To facilitate the electrical body connection, the body contact 202 can include conductive or semiconductive material, such as P−/P+ Polysilicon, Silicon, silicon-germanium (SiGe), metallic material, and/or the like. In some embodiments, the body contact 202 can include a combination of materials (e.g., semiconductive polysilicon and metallic materials). For example, the body contact can include P+ polysilicon liner followed by conductive metallic material, thereby reducing the electrical resistance of the body contact 202.

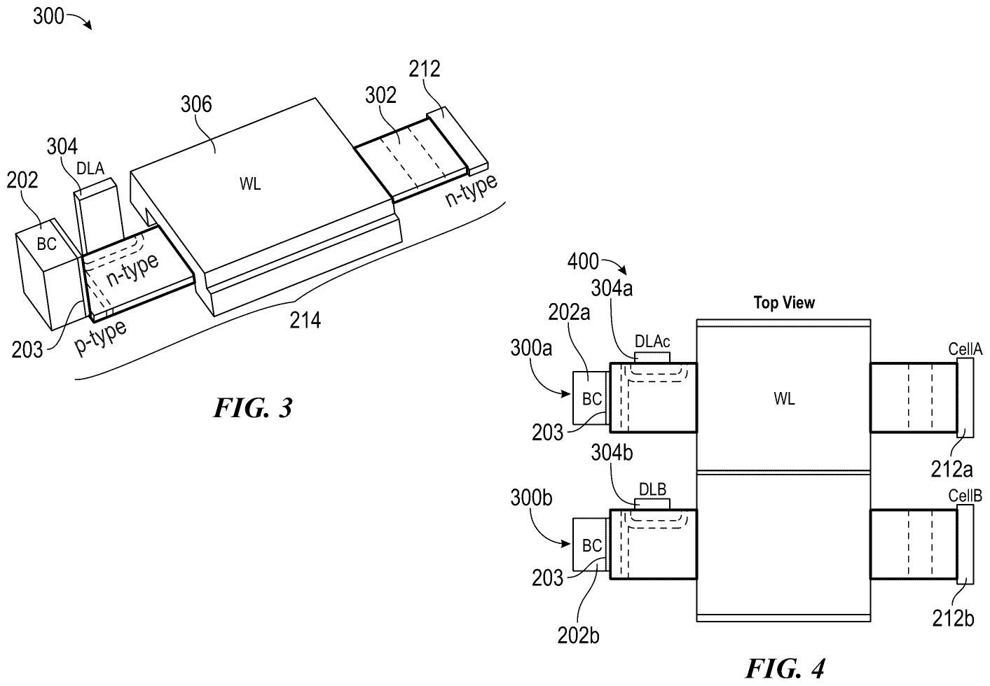

To further describe the vertical body contact 202, FIG. 3 is a perspective view of an example circuit unit 300 within the 3D semiconductor device 200 of FIG. 2 in accordance with an embodiment of the present technology. The unit 300 can represent one instance of the storage circuit 212 (e.g., a memory cell) and a related or connected instance of the access circuit 214.

The access circuit 214 can include a semiconductor substrate or body 302 extending along a lateral direction (e.g., along the associated circuit layer 204 of FIG. 2) between the storage circuit 212 and a connected DL 304. The access circuit 214 can also include a WL structure 306 located between the storage circuit 212 and the DL 304. The WL structure 306 can be a two-sided, a three-sided, or four-sided GAA structure. Alternatively, the WL structure 306 can be a one-sided structure, such as for other transistor architecture. The access circuit 214 can include a transistor having the WL structure 306 coupled to or functioning as a control or a gate terminal, the DL 304 coupled to a first end terminal (e.g., one of either a source or a drain), and the storage circuit 212 coupled to a second end terminal (e.g., the remaining one of the source or the drain complementary to the first end terminal).

The body 302 can be generally neutral or without a specific doping except at or near various connections. In some embodiments, the body 302 can have matching doping type (e.g., n-type) at locations contacting the access circuit 214 and the DL 304. The doping can weaken for portions farther away from the connected contacts (e.g., having a gradient pattern for the doping state) and remain generally neutral for portions between the contacts. For example, the portion of the body 302 overlapping the WL structure 306 can be neutral. Accordingly, the access circuit 214 can effectively be a transistor with (1) the WL structure 306 coupled to or functioning as the gate of the transistor and (2) the storage circuit 212 and the DL 304 coupled to the source and drain of the transistor. Accordingly, the body 302 can facilitate a creation of a channel between the storage circuit 212 and the DL 304 according to activation of the WL through the structure 306.

Along with the access circuit 214 and the DL 304, each circuit unit 300 can connect to the vertical body contact 202 as described above. The vertical body contact 202 can be connected to the body 302 at a location opposite the access circuit 214 across the WL structure 306. In other words, the circuit unit 300 can have the storage circuit 212 on one side of the WL structure 306 and the DL 304 and the vertical body contact 202 at the opposite side of the WL structure 306. The body 302 at or near the vertical body contact 202 can be doped opposite (e.g., p-type) the portions at or near the DL 304. Accordingly, the vertical body contact 202 can prevent the floating state of the body 302 and provide a path away from the storage circuit 212 for leakage from the DL 304, such as when the WL is inactive/off. In contrast, other traditional devices having the floating body may experience reduction in data retention since the leakage current has no other path than to flow from/to the connected data cell. As such, the vertical body contact 202 can provide at least increase in data retention capacity, decrease in data error rates, and decrease in refresh rate and the related power consumption.

FIG. 4 is a top view of a first example arrangement 400 of adjacent circuit units (e.g., adjacent instances of the circuit unit 300 of FIG. 3) in accordance with an embodiment of the present technology. For the first arrangement 400, each circuit unit can have at least one instance of the vertical body contact 202. For example, a first circuit unit 300a can be adjacent to a second circuit unit 300b along an instance of the layer 204 of FIG. 2. The first circuit unit 300a can include (1) a first storage circuit 212a that is configured to store one bit in a given stored word and (2) a first DL 304a configured to access the data at the first storage circuit 212a. Similarly, the second circuit 300b can include a second storage circuit 212b configured to store a different/adjacent bit of the stored word and a second DL 304b. Each of the first and second units can include a separate body contact. In other words, the first circuit unit 300a can include a first body contact 202a, and the second circuit unit 300b can include a second body contact 202b that is separate from the first body contact 202a.

In some embodiments, the vertical body contact 202 can be attached to the body 302 of FIG. 3 at an end thereof opposite the storage circuit 212. In other words, the body 302 can have a length with the storage circuit 212 attached to one end of the length and the vertical body contact 202 attached at another end of the length. The DL 304 for each circuit unit can be attached between the WL structure 306 and the vertical body contact 202, such as on a portion of a sidewall as illustrated in FIG. 4. Accordingly, the vertical body contact 202 can be located relatively closer to the DL 304 to remove the leakage while remaining outside of the channel between the DL 304 and the storage circuit 212.

Additionally, an intentionally-placed dielectric film 203 may be disposed between the vertical body contact 202 and the body 302. The dielectric film 203 can have a thickness (e.g., measured parallel to the length of the body 302 and the direction of current flow) that is controlled to enable hole conduction while inhibiting dopant diffusion, such as from P-type contact region into the channel or the body. In other words, the dielectric film 203 can have the thickness that is less than a predetermined threshold (e.g., less by a factor of 5, 10, or more in comparison to a dimension of the body 302 measured along a parallel direction) that is sufficient to block movement/diffusion of dopants but insufficient to block movement of electrical holes.

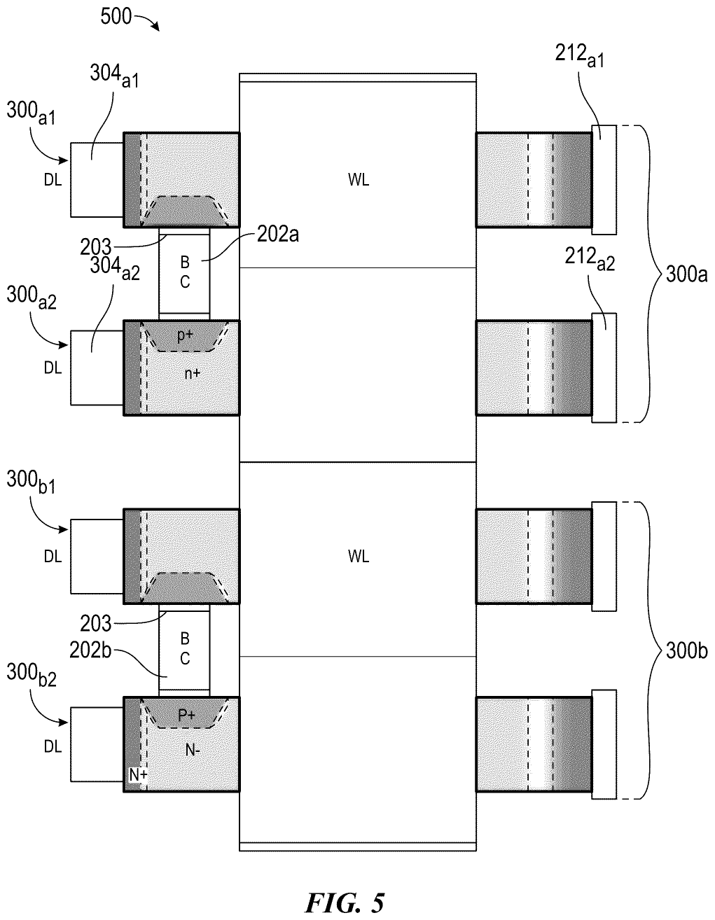

FIG. 5 is a top view of a second example arrangement 500 of adjacent circuit units (e.g., adjacent instances of the circuit unit 300 of FIG. 3) in accordance with an embodiment of the present technology. For the second arrangement 500, each vertical body contact 202 can be shared by two or more instances of the circuit unit 300. For example, a first circuit unit 300ₐ₁ can include a first storage circuit 212ₐ₁ and a first DL 304ₐ₁, and a second circuit unit 300ₐ₂ can include a second storage circuit 212ₐ₂ and a second DL 212ₐ₂. The first and second circuit units 300ₐ₁ and 300ₐ₂ can be connected to a first shared body contact 202a. Based on the shared connection to the first shared body contact 202a, the first and second circuit units 300ₐ₁ and 300ₐ₂ can belong to a first unit grouping 300a. The first unit grouping 300a can be adjacent to a second unit grouping 300b that similarly includes a second set of circuit units 300_{b1} and 300_{b2} connected to a second shared body contact 202b that is separate from the first shared body contact 202a.

In some embodiments, the common body contact (e.g., the common body contacts 202a and 202b) can be located between the lengths of connected or included circuit units. Using the first unit grouping 300a as an example, the first common body contact 202a can be located between the first and second circuit units 300ₐ₁ and 300ₐ₂ and contact mirroring or facing instances of the side peripheral edges or sidewalls of the bodies. The first unit grouping 300a can be connected between the WL structure and the DL. For such arrangements, the current carrying capacity of the vertical body contact 202 (via, e.g., contact dimension or size, a size of the body contact structure, a distance between the body contact and the WL, channel width in comparison to body width, or other similar physical parameters) can be controlled to reduce the influence of the vertical body contact 202 on the current channel.

As described above, the dielectric film 203 may be disposed between the vertical body contact 202 and the body 302. For the second example arrangement 500, the thickness of the dielectric film 203 can be measured along a direction parallel to the length of the body 302 extending between two adjacent channels. The dielectric film 203 can have the thickness configured to enable hole conduction while inhibiting dopant diffusion.

In other embodiments, the vertical body contact 202 can be located at an end of a length, similar to the unit 300 of FIG. 3, and be electrically or physically connected to multiple circuit units. For example, the body contacts 202a and 202b of FIG. 4 can be replaced by a single integral structure that connects to the substrates of the circuit units 300a and 300b.

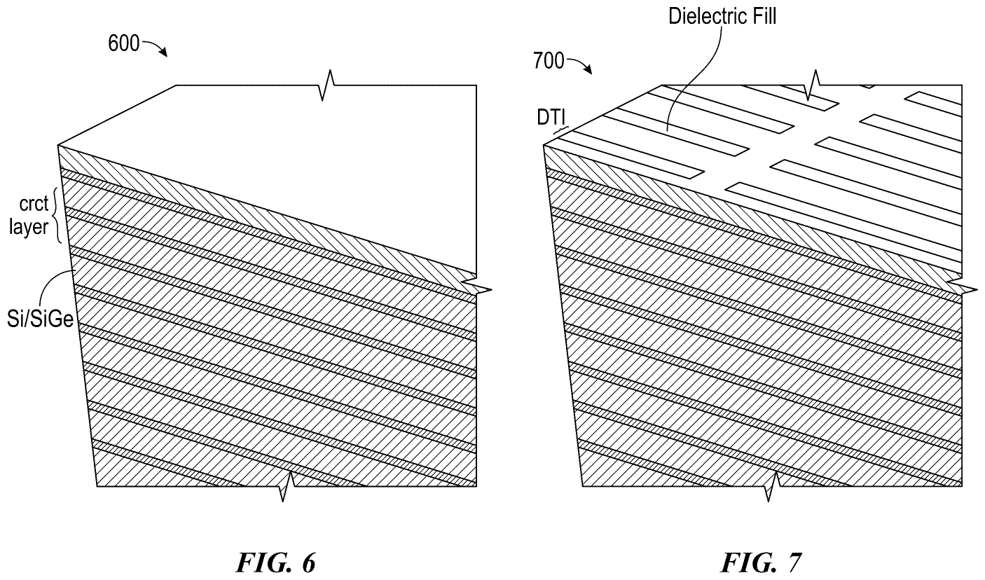

FIG. 6-FIG. 18 are example stages in manufacturing an example 3D semiconductor device in accordance with an embodiment of the present technology. For example, aspects of the process illustrated in FIG. 6-FIG. 18 can be used to manufacture the first example arrangement 400 of FIG. 4, the second example arrangement 500 of FIG. 5, and/or other similar devices including shared body contacts.

FIG. 6 is a perspective view of a portion of a structure 600 associated with (e.g., resulting from) a stack depositing stage, such as for depositing silicon (Si) and/or SiGe. The structure 600 can further include one or more hard masks for patterning or etching purposes. The structure 600 can further include the basis for the separate layers with the semiconductor material (e.g., the Si and/or the SiGe) surrounded by portions of the mask/insulation material, such as on top and bottom surfaces of the planar semiconductor material.

FIG. 7 is a perspective view of a portion of a structure 700 associated with a patterning stage, such as for forming deep trench isolations (DTIs) and/or dielectric fills. Oxide material can be deposited or formed in one or more of the patterned depressions (e.g., within the DTIs). Accordingly, the structure 700 can include the basis for separating adjacent circuits within each layer and for providing one or more vertical connections that extend through the layers.

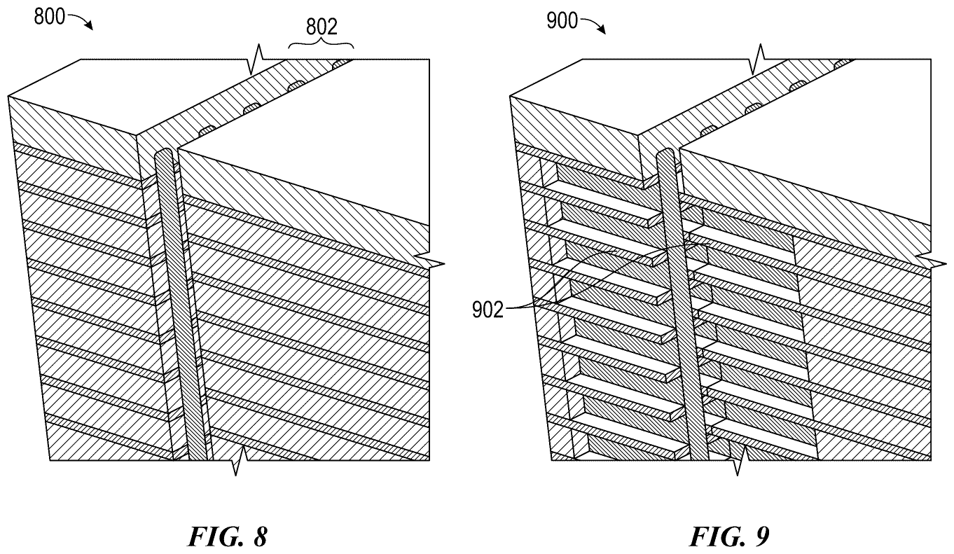

FIG. 8 is a perspective view of a portion of a structure 800 associated with a stage for a further trench patterning and etching, such as in preparation to form the WL related structures. In other words, the structure 800 can include one or more WL-forming trenches 802 that are formed according to related patterning and etching (using, e.g., chemical, light or laser, or the like) sub-stages. The WL-forming trenches 802 can extend vertically and through/across the layers, thereby allowing the capability to laterally access and shape portions of each layer. The WL-forming trenches 802 can expose one sides of the dielectric fills.

FIG. 9 is a perspective view of a portion of a structure 900 associated with a stage for exhuming portions of the semiconductor material (e.g., Si and/or SiGe) from one or more of the layers. Semiconductor structures 902 can be formed by removing the insulative material and exposing portions of the semiconductor material of FIG. 8. As a result, the structure 900 can have cavities intended to house the storage circuits 212 of FIG. 2 and/or the access circuits 214 of FIG. 2. The removal of the semiconductor material can expose further (e.g., peripheral) portions of the dielectric fills. In some embodiments, the exposed semiconductor structures 902 may be further shaped, such as to control or adjust a thickness of one or more of the semiconductor structures 902.

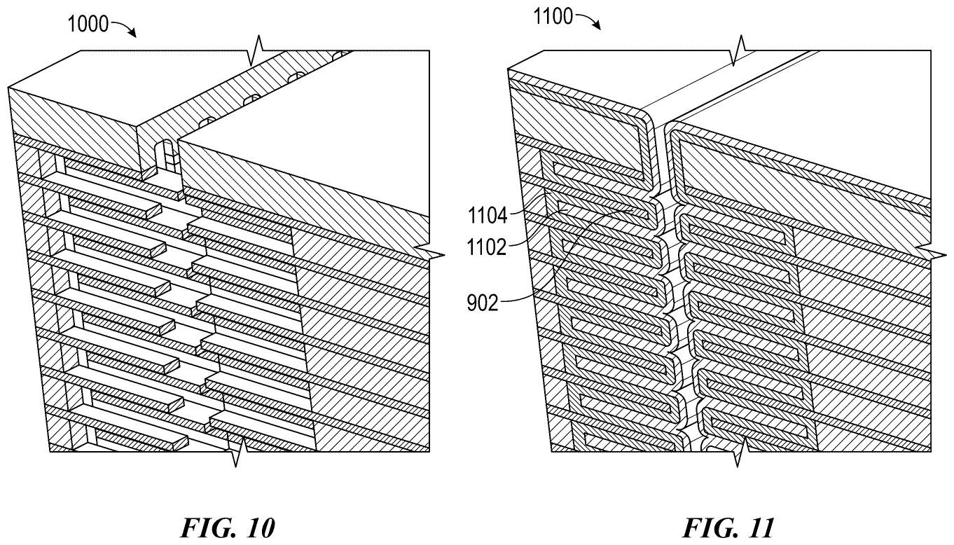

FIG. 10 is a perspective view of a portion of a structure 1000 associated with an oxide punch etching stage. For example, the structure 1000 can correspond to the structure 900 of FIG. 9 after removing exposed portions of the dielectric fills. Accordingly, the cavities therein can be enlarged further.

FIG. 11 is a perspective view of a portion of a structure 1100 associated with a stage for forming insulative material 1102 (e.g., silicon nitride (SiN)). The insulative material 1102 can be formed or deposited into the exposed surfaces of the semiconductor structures 902 and/or in the cavities. Additionally, an oxide layer 1104 may be formed or deposited over exposed portions of the insulative material 1102. Accordingly, laterally extending portions of the semiconductor material 900 can provide a basis for forming the body 302 of FIG. 3 of the access circuits 214 of FIG. 2.

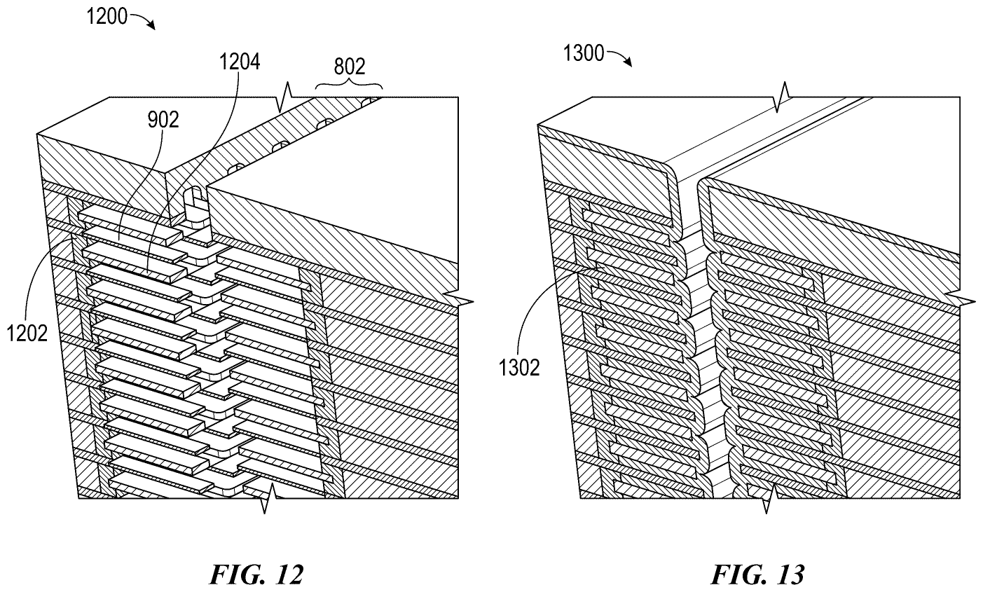

FIG. 12 is a perspective view of a portion of a structure 1200 associated with a stage for etching away portions of the oxide layer 1104 of FIG. 11. The structure 1200 can have oxide boundaries 1202 at an end portion of each semiconductor structure 902. The top and bottom surfaces of the semiconductor structures 902 may be exposed based on the etching. Insulative material 1204 remaining at a height between the semiconductor structures 902 can associated with the boundaries of layers above and below the insulative material 904. In some embodiments, the insulative material 1204 may be reshaped or recessed such that the semiconductor structures 902 extend laterally past a peripheral edge of the insulative material 904 at or near the WL-forming trenches 802.

FIG. 13 is a perspective view of a portion of a structure 1300 associated with a stage for initially forming one or more portions of the access circuit 214. For example, the structure 1300 can include a gate oxide and a metallic deposit 1302 that effectively provide a basis for the WL structure 306 of FIG. 3.

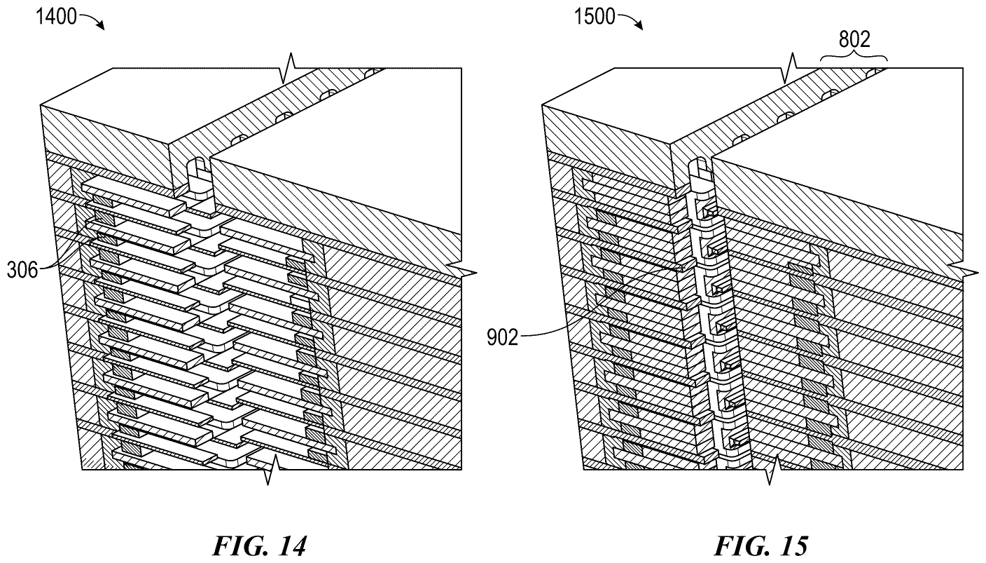

FIG. 14 is a perspective view of a portion of a structure 1400 associated with a stage for forming the gate or the WL portions of the access circuit 214. The structure 1400 can include the WL structure 306 resulting from removing portions of the metal deposit 1302 of FIG. 13. The remaining portions of the metal deposit 1302 and/or a reshaping result thereof can represent or function as the WL structure 306. Based on the shape of the cavities and the etching process, the resulting WL structure 306 can face or overlap the semiconductor structures 902 of FIG. 12 on one, two, three or four surfaces.

FIG. 15 is a perspective view of a portion of a structure 1500 associated with a stage for filling and shaping the semiconductor portions. For example, the structure 1500 can be formed by filling the cavities of the structure 1400 of FIG. 14 (e.g., resulting from removing the portions of the metal deposit 1302 of FIG. 13) with oxide or other insulative material (e.g., SiN). The deposited material can be etched or shaped to expose the semiconductor structures 902 at or about the WL-forming trenches 802. In other words, the semiconductor structures 902 can extend past peripheral edges of the insulative material and into the WL-forming trenches 802.

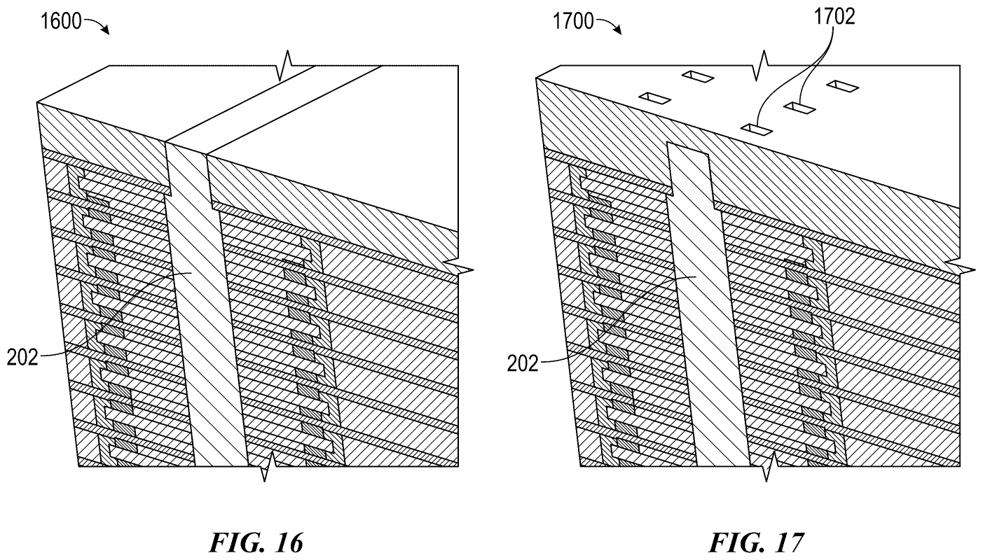

FIG. 16 is a perspective view of a portion of a structure 1600 associated with a stage for forming one or more body contact nodes 1602. For example, the structure 1600 can be a result of filling the WL-forming trenches 802 of FIG. 15 with doped semiconductor material, such by depositing as P+ polysilicon material. Accordingly, the body contact nodes 1602 can represent or include the vertical body contact 202 of FIG. 2 and extend along a vertical direction and through/across multiple layers. The vertical body contact 202 can directly contact the semiconductor structures 902 of FIG. 15 at one end that is away from the WL structure 306 of FIG. 15, the oxide boundaries 1202 of FIG. 12, and the connected storage circuit 212 of FIG. 2.

FIG. 17 is a perspective view of a portion of a structure 1700 associated with a stage for forming DL contact vias 1702. The DL contact vias 1702 can extend along a vertical direction and extend across/through the various layers. The DL contact vias 1702 can be formed using chemical or light-based reagents that etch away the materials across/through the layers. The DL contact vias 1702 can be formed using chemical or light-based reagents that etch away the materials across/through the layers. Along lateral directions, the DL contact vias 1702 can be located between the WL structure 306 and the vertical body contact 202 of FIG. 16. Further, the DL contact vias 1702 can be located at the sidewall of each of the semiconductor structures 902 of FIG. 15.

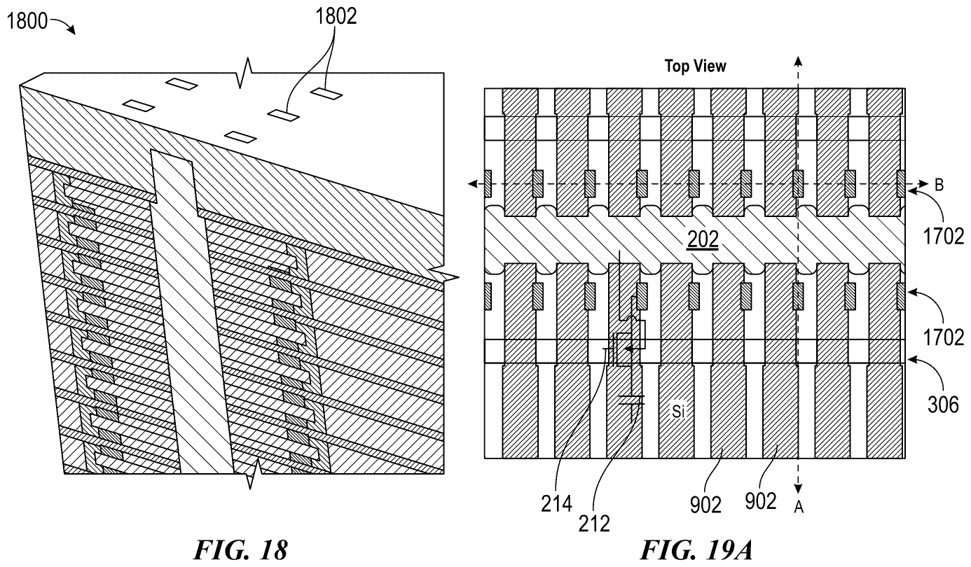

FIG. 18 is a perspective view of a portion of a structure 1800 associated with a stage for forming vertical DL connections 1802 that effectively function as or become the DL 304 of FIG. 3. The vertical DL connections 1702 can be formed by depositing metal or doped material (e.g., n+ poly) in the DL contact vias 1702. Alternatively or additionally, the vertical DL connections 1802 can be formed by gas phase doping through DL contact vias 1702.

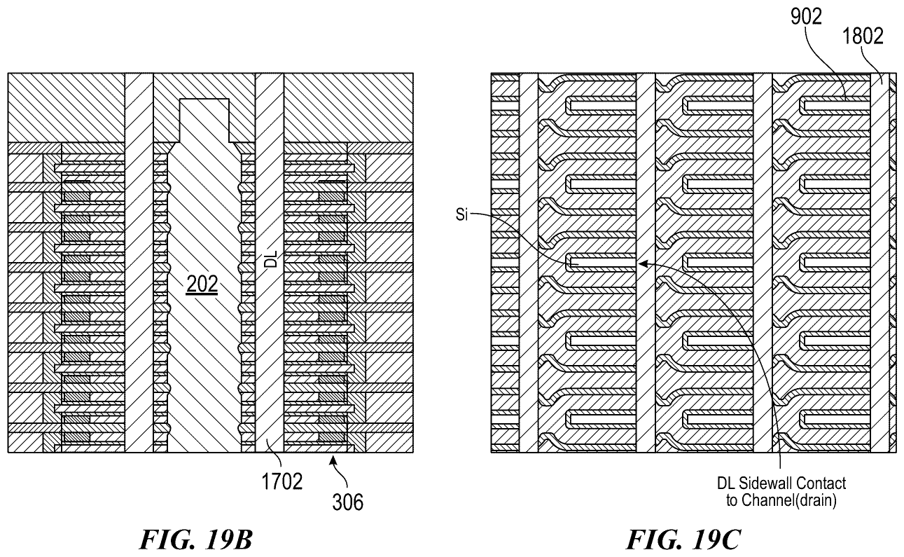

FIG. 19A-FIG. 19C are illustrations of various details regarding the first example 3D semiconductor device (e.g., the structure 1800 of FIG. 18, the arrangement 400 of FIG. 4, and/or the device 200 of FIG. 2) in accordance with an embodiment of the present technology. FIG. 19A is a top view of a portion of one layer within the structure 1800 of FIG. 18. FIG. 19B is a cross sectional view taken along a dashed line A of FIG. 19A. FIG. 19C is a cross sectional view taken along a dashed line B of FIG. 19A.

Referring now to FIG. 19A-FIG. 19C together, the vertical body contact 202 can have a width that extends across a lateral direction. The semiconductor structures 902 can be arranged in rows on opposing sides of the vertical body contact 202. The end portions of the semiconductor structures 902 can extend into and directly contact the vertical body contact 202.

The semiconductor structures 902 can be connected to components, thereby forming individual circuit units (e.g., instances of the circuit unit 300 of FIG. 3). For example, the WL structures 306 can be above, below, and/or adjacent to the semiconductor structures 902. The semiconductor structures 902 can be connected to access circuits 214 (e.g., capacitors). Also, the vertical DL connections 1702 can contact the semiconductor structures 902 between the vertical body contact 202 and the WL structures 306. The 3D semiconductor device can have sidewalls of the DL 1702 contacting the semiconductor structures 902 (and the channel/drain) as illustrated in FIG. 19C.

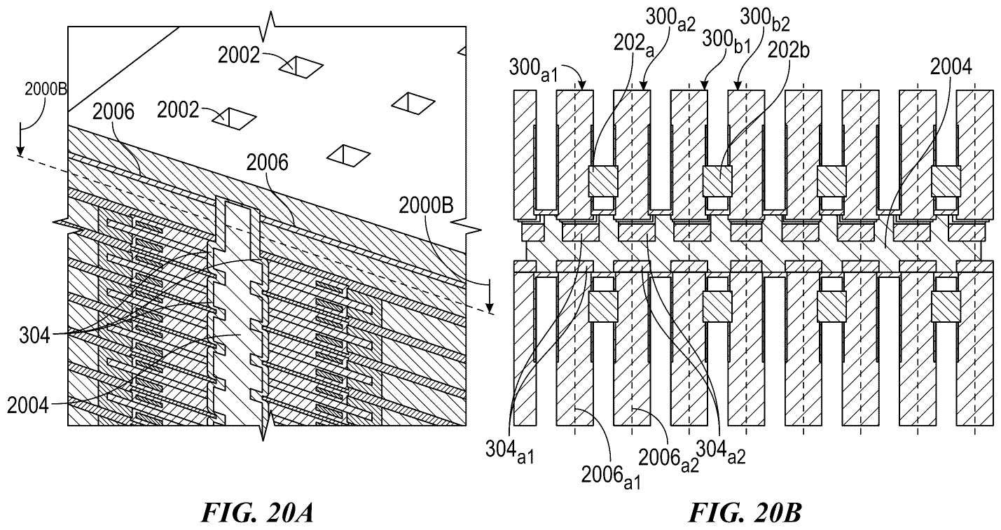

FIG. 20A and FIG. 20B are illustrations of an adjusted example stage for manufacturing the second example 3D semiconductor device (e.g., the second example arrangement 500 of FIG. 5) in accordance with an embodiment of the present technology. For example, FIG. 20A is a perspective view of a portion of a structure 2000 associated with a stage for forming body contact vias 2002. The structure 2000 can be used to manufacture the second example arrangement 500. Also, the structure 2000 can be analogous to the structure 1700 of FIG. 17 being used to manufacture the first example arrangement 400 of FIG. 4. Accordingly, the manufacturing processes leading up to and following the structure 2000 can be similar to the manufacturing process described above.

For the second example embodiment, the body contact vias 2002 can extend along a vertical direction and extend across/through the various layers, and the digit-lines 304 can occupy remaining portions of the trenches 802 of FIG. 15. In other words, locations and/or orientations of the body contact 202 and the digit-lines 304 can be interchanged between the structure 2000 and the structure 1700

The body contact vias 2002 can be formed using chemical or light-based reagents that etch away the materials across/through the layers. The body contact vias 2002 can be formed using chemical or light-based reagents that etch away the materials across/through the layers. Along lateral directions, the body contact vias 2002 can be located between the WL structure 306 and the vertical body contact 202 of FIG. 16. Further, the body contact vias 2002 can be located between and/or expose one or more sidewalls of the semiconductor structures 902 of FIG. 15.

In some embodiments, the body contact vias 2002 can be located between and/or expose opposing sidewalls of adjacent semiconductor structures. Accordingly, in comparison to the DL contact vias 1702 of FIG. 17, the body contact vias 2002 can have longer dimensions, such as to simultaneously contact the opposing sidewalls. Moreover, the structure 2000 can have a quantity of the body contact vias 2002 that is less (e.g., half of) a quantity of the DL contact vias 1702 in the structure 1700 having equal number of channels.

For the structure 2000, the digit-lines 304 can occupy remaining portions of the trenches 802. Accordingly, the digit-lines 304 can contact the body 302 of FIG. 3 at terminal ends thereof away from the storage circuit 212 of FIG. 2. The digit-line 304 can be an integral/continuous and electrically conductive structure (e.g., copper) that extend vertically across the layers and contacting terminal portions of an aligned set of channels. In some embodiments, as illustrated in FIG. 20A, A pair of digit-lines 304 can be separated by an insulator 2004 (e.g., oxide deposit). Each of the pair of digit-lines 304 can contact the terminal ends of one of the opposing sets of channels. In other embodiments the integral/continuous structure can contact the terminal ends of opposing sets of channels. In other words, the insulator 2004 and the pair of digit-lines 304 can be replaced by a continuous/integral structure that includes electrically conductive material (e.g., copper).

The digit lines 304 can be electrically connected to routing connections 2006 that extend along a lateral direction. For example, instead of accessing the digit lines 304 directly from a top portion of the structure 1802 of FIG. 18 for the first configuration, the routing connections 2006 can provide an electrical connection that may be available from one or more peripheral portions of the resulting structure. The routing connections 2006 can be formed using masks, trenches, and material deposit methods similar to the ones described above.

FIG. 20B is a top cross-sectional view of the second example arrangement 500 taken under the routing connections 2006. FIG. 20B can be analogous to FIG. 19A but for the second example arrangement 500 instead of the first example arrangement 400 of FIG. 4 illustrated in FIG. 19A. FIG. 20B can illustrate the internal portions of the second example arrangement 500 that results after the body contact vias 2002 of FIG. 20A are filled with conductive material to form the body contacts 202 of FIG. 5 and FIG. 20B. The body contacts 202 can be located between and contacting an adjacent pair of circuit units. For example, the first body contact 202a can be located between and electrically connected to the first and second circuit units 300ₐ₁ and 300ₐ₂. Also, the second body contact 202b can be located between and electrically connected to the first and second circuit units 300_{b1} and 300_{b2}.

Each of the circuit units can be connected to the DL 304 at terminal edges. For example, the circuit unit 300ₐ₁ can have the DL 304ₐ₁ connected to one end of a length opposite the storage cell. Similarly, the circuit unit 300ₐ₂ can have the DL 304ₐ₂, the circuit unit 300_{b1} can have the DL 304_{b1}, and the circuit unit 300_{b2} can have the DL 304_{b2}, and so forth connected to the corresponding ends.

Further, each of the circuit units can have a corresponding instance of the routing connections 2006 (illustrated using dashed lines in FIG. 20B) above, overlapping, and/or parallel with the length of the routing connection. For example, a routing connection 2006ₐ₁ can be located above and overlapping the circuit unit 300ₐ₁. Additionally or alternatively, the routing connection 2006ₐ₁ can extend parallel to the length of the circuit unit 300ₐ₁. Routing connections 2006ₐ₂, 2006_{b1}, and 2006_{b2}, can be arranged similarly relative to 300ₐ₂, 300_{b1}, and 300_{b2}, respectively.

For example, FIG. 20A is a perspective view of a portion of a structure 2000 associated with a stage for forming body contact vias 2002. The structure 2000 can be used to manufacture the second example arrangement 500. Also, the structure 2000 can be analogous to the structure 1700 of FIG. 17 being used to manufacture the first example arrangement 400 of FIG. 4. Accordingly, the manufacturing processes leading up to and following the structure 2000 can be similar to the manufacturing process described above.

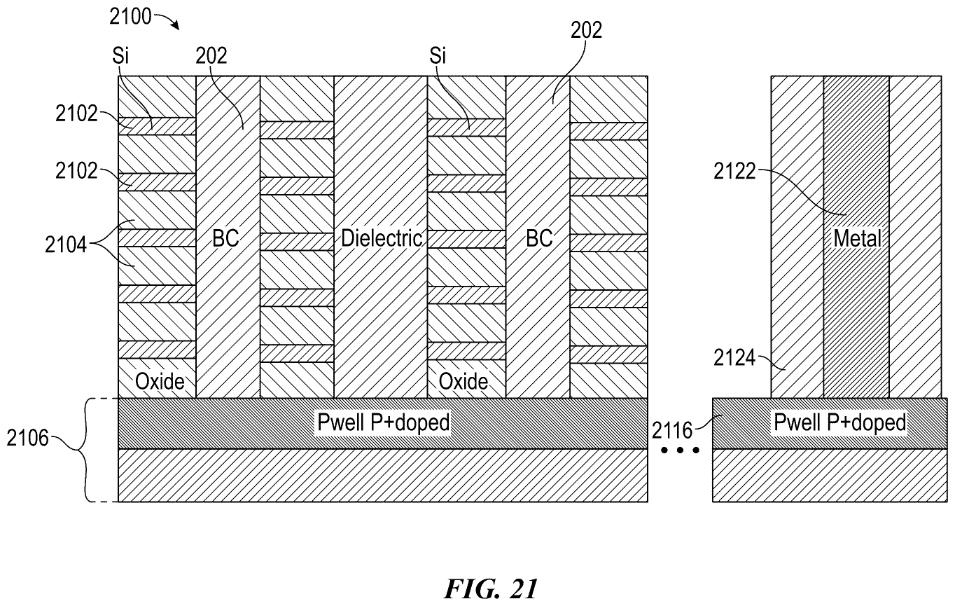

FIG. 21 is a schematic view of an example aspect of the 3D semiconductor device in accordance with an embodiment of the present technology. FIG. 21 illustrates an example portion 2100 of a structure (e.g., the memory array 150 of FIG. 1, the 3D semiconductor device 200 of FIG. 2, the first example arrangement 400 of FIG. 4, the second example arrangement 500 of FIG. 5, or other semiconductor devices) having the 3D or vertical body connections. The represented structure can include the access circuits 214 of FIG. 2 that are formed around silicon structures 2102 disposed between insulation layers 2104 (e.g., oxide layers) that electrically separate the access circuits 214 along vertical directions. The combination of the silicon structures 2102 and the insulation layers 2104 can be over and/or integral with a silicon substrate 2106.

As described above, the represented structure can include vertical body contacts 202 that electrically connect the semiconductor body 302 of FIG. 3 of the access circuits 214. The vertical body contacts 202 can directly contact the silicon structures 2102 on multiple layers and provide a connection, such as to an electrical ground, for reduced floating body effects.

In some embodiments, the 3D semiconductor device 200 can include the vertical body contacts 202 directly contacting and/or electrically coupled to a portion of the silicon substrate 2106. For example, the vertical body contacts 202 directly contact and/or electrically couple to a conductive portion 2116 (e.g., a P-well P+ doped region) of the silicon substrate 2106. The conductive portion 2116 can provide a path or a lateral layer/plane electrically coupled to the vertical body contacts 202. At least one of the insulation layers 2104 can be disposed between the silicon structures 2102 and the conductive portion 2116, thereby preventing any direct contacts between the conductive portion 2116 and the silicon structures 2102.

The conductive portion 2116 can extend along a lateral direction and electrically couple to a vertical connector 2122 (e.g., P-well). Accordingly, the conductive portion 2116 can electrically couple the vertical body contacts 202 to the vertical connector 2122, such as for connecting the vertical body contacts 202 to a common potential (e.g., ground) or an external circuit and/or a bonded structure. In some embodiments, the vertical connector 2122 can be located at an end or a peripheral portion of the array 150. Moreover, peripheral portions or surfaces of the vertical connector 2122 can be covered by a dielectric structure 2124, such as for isolating or controlling connections/contacts to the vertical connector 2122.

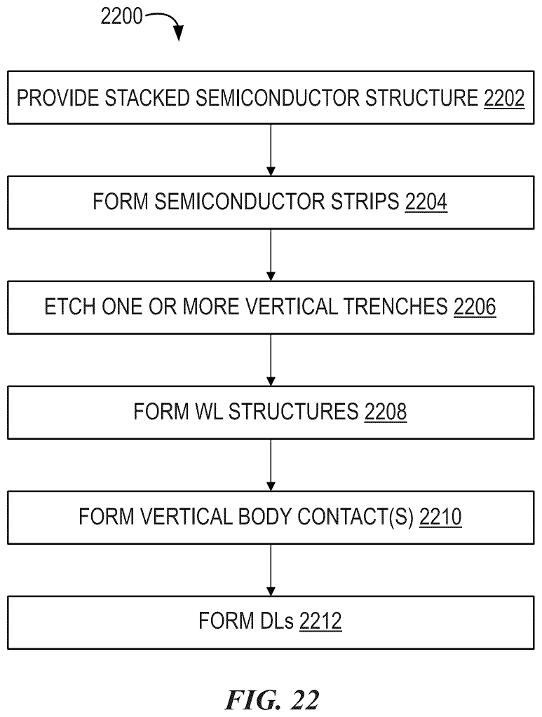

FIG. 22 is a flow diagram illustrating an example method 2200 of manufacturing a semiconductor device (e.g., the apparatus 100 of FIG. 1, the 3D semiconductor device 200, the structure 1800 of FIG. 18, or a combination thereof) with a vertical body contact (e.g., the vertical body contact 202 of FIG. 2) in accordance with an embodiment of the present technology. The method 200 can be related to (e.g., representing one or more portions or combinations of) the stages illustrated in FIG. 6-FIG. 18.

The method 2200 can include providing a stacked semiconductor structure (e.g., the structure 600 of FIG. 6), such as illustrated at block 2202. The provided structure can include layers of semiconductor material (e.g., Si/SiGe) disposed between oxide layers. Each layer of semiconductor material and surrounding portions of the oxide layers can represent a circuit layer. In some embodiments, the provided structure can include the silicon substrate 2106 of FIG. 21 having the conductive portion 2116 of FIG. 21.

At block 2204, semiconductor strips can be formed by shaping the layers of the semiconductor material, the oxide layers, or a combination thereof. For example, the semiconductor strips can be formed by etching the DTIs and depositing the dielectric fills as described above for FIG. 7. The resulting strips can be arranged in rows and columns.

At block 2206, one or more vertical trenches (e.g., the WL-forming trenches 802 of FIG. 8) can be etched. The resulting trenches can extend vertically through the semiconductor strips, the oxide layers, or a combination thereof, thereby dividing the semiconductor strips into semiconductor bodies 902 of FIG. 9 that extend along lateral directions from data storage portions toward the trenches. In addition, the vertical trenches can be leveraged to further form lateral cavities, such as described above with respect to FIG. 9 and/or FIG. 10. Accordingly, one or more portions of the semiconductor bodies 902 can be exposed through the trenches and the lateral cavities.

At block 2208, WL structures (e.g., the WL structures 306 of FIG. 3 and FIG. 14) can be formed. The formed WL structures can each be adjacent to or overlap one or more surfaces a corresponding one of the semiconductor bodies for portions located laterally between the data storage portions and the trench. In forming the WL structures, the insulative material 1102 of FIG. 11 and the oxide layer 1104 of FIG. 11 can be formed and shaped as described above for FIG. 11 and FIG. 12. As a result, the oxide boundaries 1202 of FIG. 12 may be formed to define one lateral end portions of the WL structures. Further, the etching of the oxide layer 1104 can form laterally extending cavities between adjacent semiconductor bodies as illustrated in FIG. 12. Accordingly, the laterally extending cavities can expose one or more surfaces of each of the semiconductor bodies along a portion of a length thereof.

The laterally extending cavities can be filled with a gate oxide material and a metallic material (the metallic deposit 1302 of FIG. 13) as described above for FIG. 13. The deposited metallic material can be shaped, such as by the removal or etching described above for FIG. 14. The remaining portions of the metallic material can represent or become the WL structures 306. Based on the configuration of the laterally extending cavities, the WL structures 306 can face and overlap one, two, or more surfaces of the semiconductor body. In some embodiments, the WL structure 306 can surround a portion of the length for each of the semiconductor bodies, such as for the GAA transistor structure. Moreover, the WL structure 306 can extend laterally across a row of n number of semiconductor bodies that represent an n number of storage circuits that together store a data word. Any remaining portions of the laterally extending cavities may be filled with insulative material, which may be further shaped/recessed as described above for FIG. 14 and FIG. 15.

At block 2210, one or more continuous vertical body contacts may be formed, such as by filling the one or more vertical trenches with a metallic material or a doped polysilicon material as described above for FIG. 16. The resulting vertical body contacts can be connected to columns of the semiconductor bodies.

At block 2212, the DLs (e.g., the vertical DL connections 1802 of FIG. 18) may be formed. As described above for FIG. 17 and FIG. 18, the vertical DL connections 1802 can be formed by etching the DL contact vias 1702 of FIG. 17 and then filling them with by depositing metal or doped material (e.g., n+ poly). Each of the resulting DLs can represent or include the DL 304 of FIG. 4 and contact the semiconductor body 302 of FIG. 3. The DLs can one or more sets of n matching the n number of storage circuits for the data word. The semiconductor bodies can be doped with (1) a first type (e.g., n+) at portions contacting the DL and portions interfacing with the data storage portions and (2) a second type (p+) at portions contacting the vertical body contact.

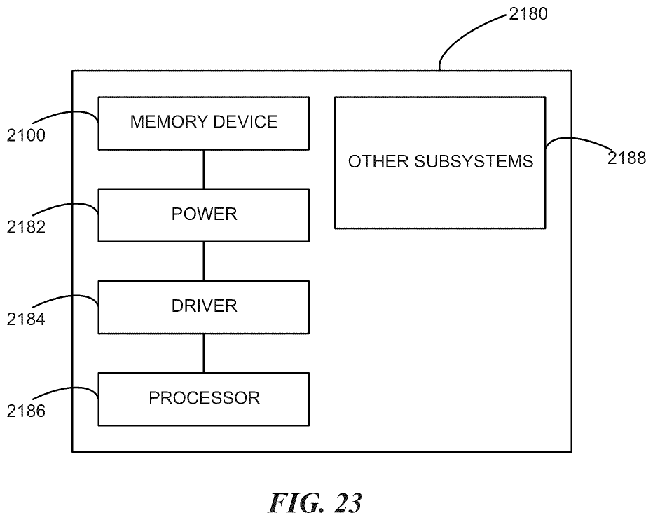

FIG. 23 is a schematic view of a system that includes an apparatus in accordance with embodiments of the present technology. Any one of the foregoing apparatuses (e.g., memory devices) described above with reference to FIGS. 1-22 can be incorporated into any of a myriad of larger and/or more complex systems, a representative example of which is system 2380 shown schematically in FIG. 23. The system 2380 can include a memory device 2300, a power source 2382, a driver 2384, a processor 2386, and/or other subsystems or components 2388. The memory device 2300 can include features generally similar to those of the apparatus described above with reference to FIGS. 1-22, and can therefore include various features for performing a direct read request from a host device. The resulting system 2380 can perform any of a wide variety of functions, such as memory storage, data processing, and/or other suitable functions. Accordingly, representative systems 2380 can include, without limitation, hand-held devices (e.g., mobile phones, tablets, digital readers, and digital audio players), computers, vehicles, appliances and other products. Components of the system 2380 may be housed in a single unit or distributed over multiple, interconnected units (e.g., through a communications network). The components of the system 2380 can also include remote devices and any of a wide variety of computer readable media.

From the foregoing, it will be appreciated that specific embodiments of the technology have been described herein for purposes of illustration, but that various modifications may be made without deviating from the disclosure. In addition, certain aspects of the new technology described in the context of particular embodiments may also be combined or eliminated in other embodiments. Moreover, although advantages associated with certain embodiments of the new technology have been described in the context of those embodiments, other embodiments may also exhibit such advantages and not all embodiments need necessarily exhibit such advantages to fall within the scope of the technology. Accordingly, the disclosure and associated technology can encompass other embodiments not expressly shown or described herein.

In the illustrated embodiments above, the apparatuses have been described in the context of DRAM devices. Apparatuses configured in accordance with other embodiments of the present technology, however, can include other types of suitable storage media in addition to or in lieu of DRAM devices, such as, devices incorporating NAND-based or NOR-based non-volatile storage media (e.g., NAND flash), magnetic storage media, phase-change storage media, ferroelectric storage media, etc.

The term “processing” as used herein includes manipulating signals and data, such as writing or programming, reading, erasing, refreshing, adjusting or changing values, calculating results, executing instructions, assembling, transferring, and/or manipulating data structures. The term data structure includes information arranged as bits, words or code-words, blocks, files, input data, system-generated data, such as calculated or generated data, and program data.

The above embodiments are described in sufficient detail to enable those skilled in the art to make and use the embodiments. A person skilled in the relevant art, however, will understand that the technology may have additional embodiments and that the technology may be practiced without several of the details of the embodiments described above with reference to FIGS. 1-23.

I/We claim:

1. A three-dimensionally integrated semiconductor memory device, comprising:
vertically stacked circuit layers that each include at least one circuit unit,
wherein each circuit unit includes (1) a storage circuit configured to store one or more bits of data and (2) an access circuit configured to provide access to and/or from the storage circuit, the access circuit having a semiconductor body, and
wherein the access circuit across the layers are aligned along a vertical direction; and
a vertical body contact extending vertically and connected to the semiconductor body of the at least one access circuit aligned across the two or more layers, wherein the vertical body contact is configured to provide a transistor body contact for multiple access circuits located on different layers.

2. The device of claim 1, wherein the access circuit includes:
the semiconductor body having a length and coupled to the storage circuit at one end of the length;
a word-line (WL) structure facing and coupled to at least one side of the semiconductor body;
a digit-line (DL) connected to the semiconductor body at a first location across the WL structure from the storage circuit; and
the vertical body contact connected to the semiconductor body at a second location across the WL structure from the storage circuit.

3. The device of claim 2, wherein:
the second location for the vertical body contact is at an opposite end of the length; and
the first location for the DL is on a portion of a sidewall of the semiconductor body and between the second location and the WL structure.

4. The device of claim 2, wherein:
the first location for the DL contact is at an opposite end of the length; and
the second location for the vertical body contact is on a portion of a sidewall of the semiconductor body and between the first location and the WL structure.

5. The device of claim 4, wherein:
the at least one circuit unit on each of the layers includes at least two circuit units positioned adjacent to each other; and
the vertical body contact is a shared body contact that is (1) located between the two circuit units and (2) connected to mirroring portions of sidewalls on semiconductor bodies of the at least two circuit units.

6. The device of claim 4, wherein:
each of the circuit layers includes a maximum number of circuit units; and
the device includes half the maximum number of vertical body contacts.

7. The device of claim 2, wherein:
the access circuit comprises a transistor formed on or integral with the semiconductor body;
the storage circuit is a capacitor connected to a first end terminal of the transistor;
the WL structure corresponds to a gate terminal of the transistor;
the DL corresponds to a second end terminal of the transistor; and
the vertical body contact corresponds to the transistor body contact configured to route leakage current away from the capacitor when the transistor is off.

8. The device of claim 7, wherein the WL structure encircles the semiconductor body along a portion of the length for a gate-all-around (GAA) transistor structure.

9. The device of claim 2, wherein the semiconductor body is doped (1) n+ type at the first location for the DL and at the one end of the length for the storage circuit and (2) p+ type at the second location for the vertical body contact.

10. The device of claim 2, wherein:
each layer includes a set of circuit units arranged along a lateral direction, the set of circuit units including an n number of storage circuits configured to store a set of bits that correspond to a stored data word;
the WL structure extends across the set of circuit units along the lateral direction and is configured to simultaneously control an n number of access circuits in the set of circuit units; and
the DL comprises an n number of DLs that (1) extend vertically across the layers and (2) each couples to an instance of the storage circuit corresponding to a unique bit position in the set of bits on each of the layers.

11. The device of claim 1, wherein portions of the semiconductor body connected to the storage circuit and the vertical body contact are doped with complementary dopant types.

12. The device of claim 1, further comprising:
a semiconductor substrate including a conductive top surface,
wherein the vertically stacked circuit layers are stacked over the semiconductor substrate, and
wherein the conductive top surface is electrically coupled to the vertical body contact and is configured to laterally route electrical signals to or from the vertical body contact.

13. The device of claim 12, further comprising:
vertical metal connection electrically coupled to the conductive top surface at a location laterally displaced from the vertical body contact, wherein the vertical metal connection is configured to electrically couple the vertical body contact to an external electrical connection.

14. The device of claim 12, wherein the conductive top surface includes a P+ doped Pwell on a top portion of the semiconductor substrate.

15. The device of claim 1, further comprising:
a dielectric film disposed between the semiconductor body and the vertical body contact, wherein the dielectric film has a thickness configured to (1) enable conduction of electrical charges or holes while (2) inhibiting dopant diffusion between the semiconductor body and the vertical body contact.

16. A three-dimensionally integrated semiconductor device, comprising:
vertically stacked circuit layers that each includes at least one transistor,
wherein each of the at least one transistor includes a first terminal, a second terminal and a gate terminal connected to or integral with a semiconductor body, the first and second terminals functioning as endpoints of a current channel, and
wherein the at least one transistor on each of the layers are aligned along a vertical direction; and
a vertical body contact extending vertically across the layers and connected to the semiconductor body of the at least one transistor on each of the layers, wherein the vertical body contact is configured to provide a transistor body contact for the transistors located on different layers.

17. The device of claim 16, wherein:
the first terminal corresponds to a first end portion of the semiconductor body;
the vertical body contact is connected to a second end portion of the semiconductor body opposite the first end portion;
the gate terminal corresponds to a structure facing a section of at least one surface of the semiconductor body between the first and second end portions; and
the second terminal corresponds to a portion of the semiconductor body between the gate terminal and the vertical body contact.

18. The device of claim 16, wherein:
the first terminal includes a first end portion of the semiconductor body;
the second terminal includes a second end portion of the semiconductor body opposite the first end portion;
the gate terminal includes a structure facing a section of at least one surface of the semiconductor body between the first and second end portions; and
the vertical body contact is connected to a portion of the semiconductor body between the gate terminal and the second terminal.

19. The device of claim 16, wherein:
at least one of the layers includes two or more transistors arranged laterally adjacent to each other; and
the vertical body contact is located between and connected to the two laterally adjacent transistors for providing a shared body contact for the two adjacent transistors in addition to the transistors aligned along the vertical direction.

20. The device of claim 16, wherein the semiconductor body is doped with (1) a first dopant type at the first and second terminals and (2) a second dopant type at a location contacting the vertical body contact.

21. A method of manufacturing a three-dimensionally integrated semiconductor memory device, the method comprising:
providing a stacked semiconductor structure having layers of semiconductor material disposed between oxide layers;
forming semiconductor strips based on shaping the layers of semiconductor material, the oxide layers, or a combination thereof, wherein the formed semiconductor strips are arranged in rows and columns;
etching a trench extending vertically through the semiconductor strips, the oxide layers, or a combination thereof, wherein the trench divides the semiconductor strips into semiconductor bodies that extend along lateral directions from corresponding data storage portions toward the trench, each of the semiconductor bodies for providing a basis of an access circuit for the corresponding data storage portion;
forming word-line (WL) structures that are each adjacent to a corresponding one of the semiconductor bodies and laterally between the data storage portions and the trench;
forming a continuous vertical body contact based on filling the trench with an electrically conductive material or a doped polysilicon material, wherein the vertical body contact is connected to the semiconductor bodies; and
forming a vertically extending digit line (DL) for each column of the semiconductor bodies, wherein each of the vertically extending DL (1) contacts the semiconductor bodies in the corresponding column and (2) is located between the WL structures for the contacted semiconductor bodies and the continuous vertical body contact.

22. The method of claim 21, wherein forming the WL structures includes:
forming laterally extending cavities at least between the semiconductor bodies;
filling the laterally extending cavities with metallic material; and
removing portions of the metallic material from the laterally extending cavities, wherein remaining portions of the metallic material correspond to the WL structures.

23. The method of claim 22, wherein:
the laterally extending cavities expose all sides of each of the semiconductor bodies along a portion of a length thereof; and
the WL structures surround the portion of the length for each of the semiconductor bodies for a gate-all-around (GAA) transistor structure.

24. The method of claim 21, wherein the semiconductor bodies are doped with (1) a first type at portions contacting the DL and portions interfacing with the data storage portions and (2) a second type at portions contacting the vertical body contact.

25. The method of claim 21, wherein:
each of the formed WL structures extends across a row of an n number of the semiconductor bodies that correspond to an n number of storage circuits that together store a data word; and
forming the DL for each column of the semiconductor bodies includes forming an n number of DLs that each correspond to one of the semiconductor bodies in the row for providing access to corresponding bit in the data word.
